(19) United States
(12) Patent Application Publication
(10) Pub. No.: US 2024/0018664 A1
(43) Pub. Date: Jan. 18, 2024

(54) METHOD FOR CONTROLLING THE SURFACE GLOSSINESS OF METAL WORKPIECE AND METHOD FOR PREPARING METAL FILM

(71) Applicant: CHANGXIN MEMORY TECHNOLOGIES, INC., Hefei City, Anhui (CN)

(72) Inventor: Denghui WU, Hefei City, Anhui (CN)

(73) Assignee: CHANGXIN MEMORY TECHNOLOGIES, INC., Hefei City, Anhui (CN)

(21) Appl. No.: 17/605,550

(22) PCT Filed: Jul. 28, 2021
(86) PCT No.: PCT/CN2021/108987

§ 371 Date: Jan. 19, 2023

(30) Foreign Application Priority Data
Jul. 13, 2021 (CN) 202110790618.2

(51) Int. Cl. C23F 3/00; G01N 21/57

(52) U.S. Cl. CPC C23F 3/00; G01N 21/57

(57) ABSTRACT

A method for controlling a surface glossiness of a metal workpiece includes: providing a metal workpiece; detecting the surface glossiness of the metal workpiece to obtain a first detection value; and, treating the metal workpiece by different processes according to different first detection values so that the surface glossiness of the metal workpiece satisfies the production requirements.

### CROSS-REFERENCE TO RELATED APPLICATIONS

The present disclosure claims priority to the Chinese Patent Application No. 202110790618.2, entitled “METHOD FOR CONTROLLING THE SURFACE GLOSSINESS OF METAL WORKPIECE AND METHOD FOR PREPARING METAL FILM”, filed to the CNIPA on Jul. 13, 2021, which is incorporated herein by reference in its entirety.

### TECHNICAL FIELD

The present disclosure relates to the field of semiconductor integrated circuits, particularly to a method for controlling the surface glossiness of a metal workpiece and a method for preparing a metal film, and specifically to a method for controlling the surface glossiness of a metal workpiece, a metal workpiece and a method for preparing a metal film.

### BACKGROUND

In the processes for semiconductor integrated circuits, particularly in the process for preparing metal films by chemical vapor deposition, the environmental change of the reaction chamber of the device will seriously affect the performances of the metal films and thus affect the yield of products. In the process for preparing metal films (e.g., wafers) in a reaction chamber, as the use time and the number of use increases, the surface of the metal workpiece in the reaction chamber gradually becomes darker and has reduced glossiness. According to the theory of heat radiation and heat reflection, the surface glossiness of the metal workpiece will directly affect the temperature of forming the metal film and thus affect the resistivity and thickness uniformity of the metal film. This is more obvious for a vacuum process in a smaller reaction space. For a nanoscale process, a slight temperature change will directly result in product abnormities and thus affect the yield of wafers. The existing solutions are mainly to replace new materials or adjust the process temperature for improvement, but will increase the production cost, reduce the process stability and cause the uncontrollable product quality. In addition, since the appropriate surface glossiness of the metal workpiece is not studied for different process temperatures, adjusting the process temperature will affect the electrical properties of products. For example, if the process temperature is adjusted by more than 5° C., abnormalities such as the electric leakage of the electrode plate will occur.

### SUMMARY

The following is the summary of the subject described in detail in the present disclosure. This summary is not intended to limit the protection scope defined by the claims.

The present disclosure provides a method for controlling the surface glossiness of a metal workpiece, a metal workpiece and a method for preparing a metal film.

In accordance with a first aspect of the present disclosure, a method for controlling the surface glossiness of a metal workpiece is provided, comprising:
providing a metal workpiece;
detecting the surface glossiness of the metal workpiece to obtain a first detection value;
when the first detection value is less than or equal to a first threshold, treating the metal workpiece by a first treatment process so that the surface glossiness of the metal workpiece is not less than a second threshold;
when the first detection value is greater than the first threshold but less than the second threshold, treating the metal workpiece by a second treatment process so that the surface glossiness of the metal workpiece is not less than the second threshold; and
when the first detection value is greater than or equal to the second threshold, not treating the metal workpiece so that the surface glossiness of the metal workpiece is not less than the second threshold.

In accordance with a second aspect of the present disclosure, a metal workpiece is provided, which is formed by the control method described in the present disclosure, the surface glossiness of the metal workpiece being not less than a second threshold.

In accordance with a third aspect of the present disclosure, a method for preparing a metal film using the metal workpiece described in the present disclosure is provided, comprising:
determining a preset temperature according to a process for preparing a metal film;
selecting a metal workpiece with a certain surface glossiness according to the preset temperature;
mounting the metal workpiece in a reaction chamber; and
in the reaction chamber, finely adjusting a temperature in the reaction chamber according to the surface glossiness of the metal workpiece, and forming a metal film by a film deposition method.

When the glossiness of the metal workpiece does not satisfy the production requirements, the surface glossiness of the metal workpiece in the reaction chamber is improved by using the method for controlling the surface glossiness of a metal workpiece according to the present disclosure. According to the theory of heat radiation and heat reflection, when there is a metal workpiece with a high glossiness in the reaction chamber, the surface temperature and heat uniformity of the metal film can be improved, so that the resistivity of the metal film is reduced and the thickness uniformity of the metal film is improved. Meanwhile, by using the control method according to the present disclosure, it is convenient and fast to treat the metal workpiece at a high success rate, the service life of the metal workpiece can be prolonged, and the production cost can be reduced.

### BRIEF DESCRIPTION OF THE DRAWINGS

The drawings incorporated into the specification and constituting a part of the specification show the embodiments of the present disclosure, and are used with the description to explain the principles of the embodiments of the present disclosure. The drawings to be described hereinafter are some but not all of the embodiments of the present disclosure. Those skilled in the art can obtain other drawings according to these drawings without paying any creative effort.

FIG. 1 is a schematic flowchart of a method for controlling the surface glossiness of a metal workpiece according to an embodiment of the present disclosure;

FIG. 2 is a schematic flowchart of a method for preparing a metal film according to an embodiment of the present disclosure; and

FIG. 3 is a schematic flowchart of another method for preparing a metal film according to an embodiment of the present disclosure.

### DETAILED DESCRIPTION

In order to make the objectives, technical solutions and advantages of the embodiments of the present disclosure clearer, the technical solutions in the embodiments of the present disclosure will be described below clearly and completely with reference to the drawings in the embodiments of the present disclosure. Apparently, the embodiments to be described are some but not all of the embodiments of the present disclosure. All other embodiments obtained on the basis of the embodiments in the present disclosure by those skilled in the art without paying any creative effort shall fall into the protection scope of the present disclosure. It is to be noted that the embodiments of the present disclosure and the features in the embodiments can be arbitrarily combined with each other if not conflicted.

In the field of semiconductors, during the preparation of metal films (wafers) in a reaction chamber, the environmental change of the reaction chamber will seriously affect the performance of the metal films. When a metal workpiece is used as a reaction chamber for preparing a metal film, according to the theory of heat radiation and heat reflection, the surface glossiness of the metal workpiece directly affects the temperature of forming the metal film and thus affect the resistivity and thickness uniformity of the metal film. As the use time and the number of use increases, the surface of the metal workpiece in the reaction chamber gradually becomes darker and has reduced glossiness, so that the surface temperature and heat uniformity of the metal film are reduced, and the resistivity and thickness uniformity of the metal film are thus affected. This is more obvious for a vacuum process in a smaller reaction space. For a nanoscale process, a slight temperature change will directly result in product abnormities and thus affect the yield of wafers. The present disclosure provides a method for controlling the surface glossiness of a metal workpiece, which is used to treat a metal workpiece with a surface glossiness that does not satisfy the production requirements so as to improve the surface glossiness of the metal workpiece in the reaction chamber. When the metal workpiece in the reaction chamber has a high glossiness, the surface temperature and heat uniformity of the metal film can be improved, so that the resistivity of the metal film is reduced and the thickness uniformity of the metal film is improved. Meanwhile, by using the control method according to the present disclosure, it is convenient and fast to treat the metal workpiece at a high success rate, the service life of the metal workpiece can be prolonged, and the production cost can be reduced.

The specific implementations of the method for controlling the surface glossiness of a metal workpiece, the metal workpiece and the method for preparing a metal film according to the present disclosure will be described in detail below with reference to the drawings.

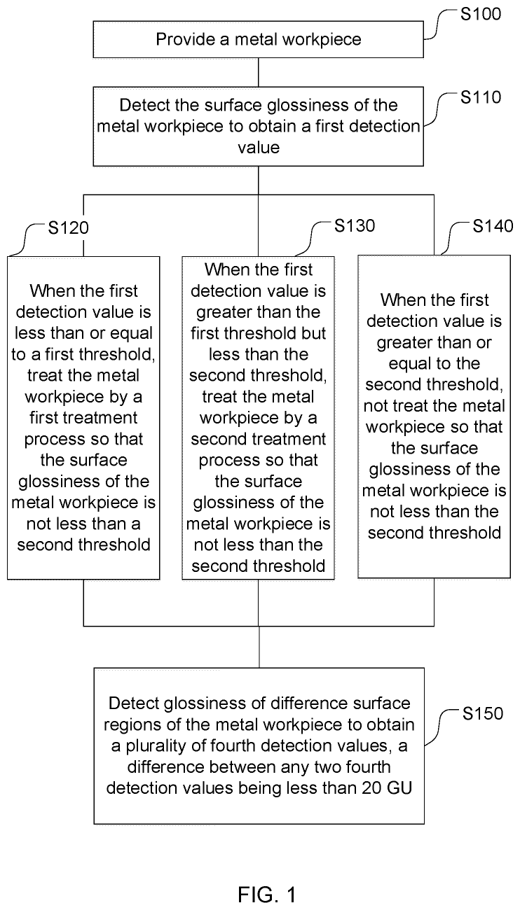

As shown in FIG. 1, an embodiment of the present disclosure provides a method for controlling the surface glossiness of a metal workpiece, comprising the following steps.
S100: A metal workpiece is provided.
S110: The surface glossiness of the metal workpiece is detected to obtain a first detection value.

The surface glossiness of the metal workpiece is detected by a glossiness detector. The glossiness of a certain surface region of the metal workpiece may be detected, or the glossiness of a plurality of surface regions of the metal workpiece may be detected. The glossiness values of a plurality of surface regions may be or may not be exactly the same. The first detection value may be obtained according to one glossiness value, or the first detection value may be obtained according to a plurality of glossiness values.
S120: When the first detection value is less than or equal to a first threshold, the metal workpiece is treated by a first treatment process so that the surface glossiness of the metal workpiece is not less than a second threshold.
S130: When the first detection value is greater than the first threshold but less than the second threshold, the metal workpiece is treated by a second treatment process so that the surface glossiness of the metal workpiece is not less than the second threshold.

When the surface glossiness of the metal workpiece is less than the second threshold, the metal workpiece is treated by the first treatment process or the second treatment process to remove the impurities adhered onto the surface of the metal workpiece, so that the surface glossiness of the metal workpiece is improved. Thus, the heat reflectivity of the surface of the metal workpiece is improved, the actual heating condition of the metal film is improved, and the resistivity of the metal film is reduced. Moreover, since the metal workpiece used for a long term has difference glossiness in different surface regions, the difference in glossiness is sometimes very large, thus greatly affecting the thickness uniformity of the metal film. By treating by the first treatment process or the second treatment process, the difference in glossiness of the surface of the metal workpiece is improved, thereby improving the thickness uniformity of the metal film.

Different first detection values indicate that the thickness or number of impurities on the surface of the metal workpiece is different. By selecting different treatment processes, the treatment on the metal workpiece may be more targeted, thereby improving the impurity removal rate and effect.
S140: When the first detection value is greater than or equal to the second threshold, the metal workpiece is not treated so that the surface glossiness of the metal workpiece is not less than the second threshold.

When the surface glossiness of the metal workpiece is greater than or equal to the second threshold, the metal workpiece may be directly used in the reaction chamber for preparing a metal film, without any treatment.

As shown in FIG. 1, in some embodiments of the present disclosure, after the surface glossiness of the metal workpiece is not less than the second threshold, the control method further comprises S150: detecting the glossiness of different surface regions of the metal workpiece to obtain a plurality of fourth detection values, the difference between any two fourth detection values being less than 20 GU.

When the difference between any two fourth detection values is greater than or equal to 20 GU, the metal workpiece is treated locally, and only the surface region of the metal workpiece having a lower fourth detection value (lower glossiness) is treated to increase the fourth detection value (glossiness) of this region, until the difference between the two fourth detection values is less than 20 GU.

In some embodiments of the present disclosure, the detecting the surface glossiness of the metal workpiece to obtain a first detection value comprises:
detecting glossiness of a plurality of surface regions of the metal workpiece to obtain a plurality of glossiness detection values, obtaining an average glossiness detection value according to the plurality of glossiness detection values, and using the average glossiness detection value as a first detection value.

In some other embodiments of the present disclosure, the detecting the surface glossiness of the metal workpiece to obtain a first detection value comprises:
detecting glossiness of a plurality of surface regions of the metal workpiece to obtain a plurality of glossiness detection values, comparing the plurality of glossiness detection values to obtain the smallest glossiness detection value, and using the smallest glossiness detection value as a first detection value.

When the glossiness of a plurality of surface regions of the metal workpiece is detected to obtain the first detection value, a plurality of surface regions of the metal workpiece may be arbitrarily selected for glossiness detection, or a plurality of uniformly distributed surface regions of the metal workpiece may be selected for glossiness detection. The selecting a plurality of uniformly distributed surface regions in the metal workpiece may be arbitrary, and will not be limited in the present disclosure.

In some embodiments of the present disclosure, the treating the metal workpiece by a first treatment process comprises the following steps.
S121: The metal workpiece is treated in a first acid solution for 15 to 25 min, then taken out and treated in a first alkali solution for 20 to 40 min, and taken out and treated in a second acid solution for 5 to 15 s. The first acid solution is one or more of hydrochloric acid, nitric acid and acetic acid; the first alkali solution is sodium hydroxide solution; and the second acid solution is one or more of hydrochloric acid, nitric acid and acetic acid. Specifically, the first acid solution is a mixed solution of hydrochloric acid, nitric acid and acetic acid; the first alkali solution is sodium hydroxide solution; and the second acid solution is a mixed solution of hydrochloric acid, nitric acid and acetic acid.
S122: The surface glossiness of the treated metal workpiece is detected to obtain a second detection value.
S123: If the second detection value is less than the second threshold, the treated metal workpiece is treated in the second acid solution for 5 to s, the surface glossiness of the metal workpiece newly treated is detected, the previous second detection value is replaced with the surface glossiness value newly obtained as the second detection value until the second detection value is not less than the second threshold.

When the first detection value is less than or equal to the first threshold, it is indicated that there are many impurities on the surface of the metal workpiece, and the metal workpiece is successively treated in the first acid solution, the first alkali solution and the second acid solution for the corresponding time to remove the impurities on the surface of the metal workpiece, so that the surface glossiness of the metal workpiece is improved. The surface glossiness of the metal workpiece subjected to the impurity removal is detected to obtain a second detection value. If the second detection value is less than the second threshold, it is indicated that the surface glossiness of the metal workpiece does not satisfy the requirements, and the metal workpiece needs to be treated in the second acid solution again, until the surface glossiness of the metal workpiece is not less than the second threshold. Otherwise, the operation of treating the metal workpiece in the second acid solution is repeated. The first acid solution can remove the impurities on the surface of the metal workpiece and can also soften the oxide film on the surface of the metal workpiece, so that the subsequent impurity removal operation can be performed smoothly. The first alkali solution is used to remove the impurities on the surface of the metal workpiece. The second acid solution can remove the impurities on the surface of the metal workpiece, and can also neutralize the excessive first alkali solution on the surface of the metal workpiece.

In some embodiments of the present disclosure, the treating the metal workpiece by a second treatment process comprises the following steps.
S131: The metal workpiece is treated in a second alkali solution for 40 to 60 min, then taken out and treated in a third acid solution for 5 to 15 s. The second alkali solution is sodium hydroxide solution, and the third acid solution is one or more of hydrochloric acid, nitric acid and acetic acid. Specifically, the second alkali solution is sodium hydroxide solution, and the third acid solution is a mixed solution of hydrochloric acid, nitric acid and acetic acid.
S132: The surface glossiness of the treated metal workpiece is detected to obtain a third detection value.
S133: If the third detection value is less than the second threshold, the treated metal workpiece is treated in the third acid solution for 5 to 15 s, the surface glossiness of the metal workpiece newly treated is detected, and the previous third detection value is replaced with the surface glossiness value newly obtained as the third detection value until the third detection value is not less than the second threshold.

When the first detection value is greater than the first threshold but less than the second threshold, it is indicated that the impurities on the surface of the metal workpiece are relatively reduced, and the metal workpiece is successively treated in the second alkali solution and the third acid solution for the corresponding time to remove the impurities on the surface of the metal workpiece, so that the surface glossiness of the metal workpiece is improved. The surface glossiness of the metal workpiece subjected to the impurity removal is detected to obtain a third detection value. If the third detection value is less than the second threshold, it is indicated that the surface glossiness of the metal workpiece does not satisfy the requirements, and the metal workpiece needs to be treated in the third acid solution again, until the surface glossiness of the metal workpiece is not less than the second threshold. Otherwise, the operation of treating the metal workpiece in the third acid solution is repeated. Since the impurities on the surface of the metal workpiece are relatively reduced, it is unnecessary to soften the oxide film on the surface of the metal workpiece before it is placed in the second alkali solution. The second alkali solution is used to remove the impurities on the surface of the metal workpiece, and can also neutralize the excessive second alkali solution on the surface of the metal workpiece.

The surface glossiness of the metal workpiece is detected by a glossiness detector. The glossiness of a certain surface region of the metal workpiece may be detected, or the glossiness of a plurality of surface regions of the metal workpiece may be detected. The glossiness values of a plurality of surface regions may be or may not be exactly the same. The second detection value or the third detection value may be obtained according to one glossiness value, or the second detection value or the third detection value may be obtained according to a plurality of glossiness values. When there are a plurality of glossiness values, an average glossiness value can be obtained according to the plurality of glossiness values and used as the second detection value or the third detection value.

When the difference between any two fourth detection values is greater than or equal to 20 GU and when the metal workpiece is treated locally, the treatment may be performed by the operations in S121 or S131.

In some embodiments of the present disclosure, the first threshold is 0 to 200 GU, the second threshold is 150 to 500 GU, and the first threshold is less than the second threshold.

Specifically, the first threshold is 50 GU, 100 GU, 150 GU, 180 GU or 200 GU, and the second threshold is 150 GU, 200 GU, 250 GU, 300 GU, 350 GU, 400 GU, 450 GU or 500 GU.

In some embodiments of the present disclosure, in the control method, the second detection value is less than a third threshold, wherein the third threshold is 700 GU, and the third threshold is greater than the second threshold.

An embodiment of the present disclosure further provides a metal workpiece, which is formed by the method for controlling the surface glossiness of a metal workpiece according to the present disclosure, the surface glossiness of the metal workpiece being not less than a second threshold.

The second threshold is an important numerical value reflecting the surface glossiness of the metal workpiece. When the surface glossiness of the metal workpiece is not less than the second threshold, the metal workpiece has sufficient heat reflectivity, so that the surface temperature and heat uniformity of the metal film can be improved, the resistivity of the metal film can be reduced, and the thickness uniformity of the metal film can be improved. The second threshold may be 150 to 500 GU.

In this embodiment of the present disclosure, in the metal workpiece, the difference in glossiness between any two surface regions is less than 20 GU.

In some embodiments of the present disclosure, the glossiness of surface regions of the metal workpiece is exactly the same.

In other embodiments of the present disclosure, the glossiness of surface regions of the metal workpiece is not exactly the same. There are a maximum glossiness value and a minimum glossiness value, and the difference between the maximum glossiness value and the minimum glossiness value is less than 20 GU.

Due to different surface glossiness of the metal workpiece, the heat reflectivity is also different. If there is a difference in glossiness on the surface of the metal workpiece, the actual temperature of the metal film will forms a regional difference, thus affecting the thickness uniformity of the metal film. Therefore, in order to ensure the thickness uniformity of the metal film, the glossiness of each surface region of the metal workpiece cannot be too different, and the difference in glossiness between any two surface regions is less than 20 GU.

In some embodiments of the present disclosure, the metal workpiece obtained by the glossiness control method according to the present disclosure needs to be tested on the machine before it is formally used. Testing on the machine comprises: the obtained metal workpiece is mounted in a reaction chamber, a metal film is formed by a film deposition method, and it is tested whether the resistivity and thickness uniformity of the metal film are qualified.

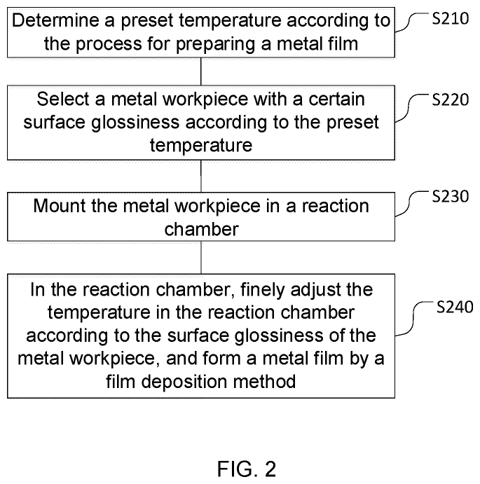

As shown in FIG. 2, an embodiment of the present disclosure further provides a method for preparing a metal film using the metal workpiece according to the present disclosure, comprising the following steps.
S210: A preset temperature is determined according to the process for preparing a metal film.
S220: A metal workpiece with a certain surface glossiness is selected according to the preset temperature.
S230: The metal workpiece is mounted in a reaction chamber.
S240: In the reaction chamber, the temperature in the reaction chamber is finely adjusted according to the surface glossiness of the metal workpiece, and a metal film is formed by a film deposition method.

The preset temperature is a reaction temperature. By controlling a certain glossiness at a certain reaction temperature and finely adjusting the reaction temperature, the resistivity and thickness uniformity of the metal film can be improved by using a metal workpiece with an appropriate glossiness and finely adjusting the reaction temperature, so that the electrical properties of the products are improved. Meanwhile, the appropriate surface glossiness of the metal workpiece will increase the maintenance period of the reaction chamber and prolong the service life of the reaction chamber.

In the embodiment of the present disclosure, the temperature of the reaction chamber is not much different from the preset temperature, and the temperature of the reaction chamber is finely adjusted based on the preset temperature. The finely-adjusted temperature does not exceed 10° C., or 3° C. During the preparation process, when the debugging temperature is within the finely-adjusted temperature and the metal film with suitable performance cannot be prepared, a metal workpiece with a more appropriate glossiness can be replaced.

In some embodiments of the present disclosure, the selecting a metal workpiece with a certain surface glossiness according to the preset temperature comprises: selecting a metal workpiece with a surface glossiness of 150 to 500 GU when the preset temperature is 450° C. to 550° C.

If the surface glossiness of the metal workpiece in the reaction chamber is too high or too low, the process debugging temperature will be beyond the adjustable space, resulting in electrical abnormities of products. When it is determined that the preset temperature is 450° C. to 550° C., a metal workpiece with a surface glossiness of 150 to 500 GU is selected, and the temperature in the reaction chamber is finely adjusted, so that the reaction process can be relatively stable, and a metal film with stable resistivity and good thickness uniformity is obtained.

In some embodiments of the present disclosure, the selecting a metal workpiece with a certain surface glossiness according to the preset temperature comprises: selecting a metal workpiece with a surface glossiness of 240 to 500 GU when the preset temperature is 450° C. to 500° C.

In some embodiments of the present disclosure, the selecting a metal workpiece with a certain surface glossiness according to the preset temperature comprises: selecting a metal workpiece with a surface glossiness of 150 to 300 GU when the preset temperature is 500° C. to 550° C.

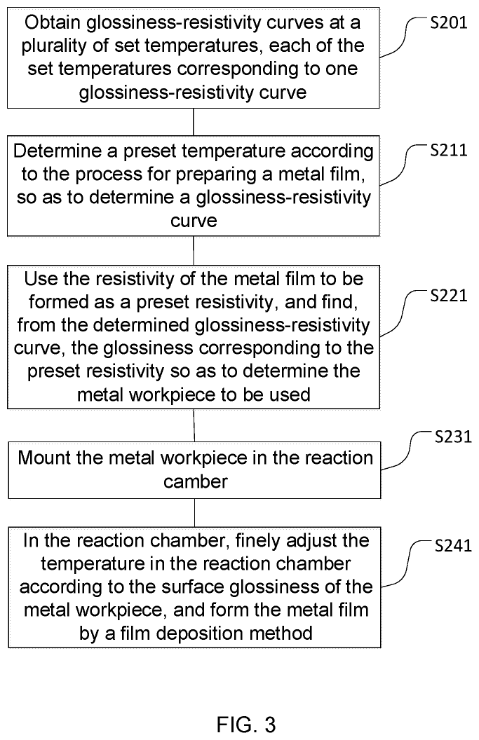

As shown in FIG. 3, in some embodiments of the present disclosure, the method for preparing a metal film comprises the following steps.
S201: Glossiness-resistivity curves are obtained at a plurality of set temperatures, each of the set temperatures corresponding to one glossiness-resistivity curve.
S211: A preset temperature is determined according to the process for preparing a metal film, so as to determine a glossiness-resistivity curve.
S221: The resistivity of the metal film to be formed is used as a preset resistivity, and the glossiness corresponding to the preset resistivity is found from the determined glossiness-resistivity curve so as to determine the metal workpiece to be used.
S231: The metal workpiece is mounted in the reaction chamber.
S241: In the reaction chamber, the temperature in the reaction chamber is finely adjusted according to the surface glossiness of the metal workpiece, and the metal film is formed by a film deposition method.

In some embodiments of the present disclosure, the obtaining glossiness-resistivity curves comprises: in a reaction chamber, setting the temperature in the reaction chamber as the set temperature, and forming metal films with different resistivity by mounting metal workpieces with different surface glossiness, to obtain linear curves of glossiness and resistivity, one glossiness corresponding to one resistivity.

In some embodiments of the present disclosure, in the obtaining glossiness-resistivity curves, in addition to the temperature in the reaction chamber, other parameters need to be defined, for example, the thickness of the metal film.

In some embodiments of the present disclosure, the metal film is a tungsten-containing metal film or a titanium-containing metal film.

In some embodiments of the present disclosure, the resistivity of the metal film is 2000 to 2500 μΩ·cm.

Specifically, the resistivity of the metal film may be 2000 μΩ·cm, 2100 μΩ·cm, 2200 μΩ·cm, 2300 μΩ·cm, 2400 μΩ·cm or 2500 μΩ·cm.

Various embodiments or implementations in this specification have been described progressively, and each embodiment focuses on the differences from other embodiments, so the same and similar parts of the embodiments may refer to each other.

In the description of this specification, the description with reference to terms “an embodiment”, “an exemplary embodiment”, “some embodiments”, “other embodiments”, “an illustrative implementation” or “an example” means that specific features, structures, materials or characteristics described with reference to the implementation or example are included in at least one implementation or example of the present application.

In this specification, the schematic expressions of the terms do not necessarily refer to the same implementation or example. In addition, the described specific features, structures, methods or characteristics may be combined in any one or more implementations or examples in a suitable way.

In the description of the present disclosure, it is to be noted that the terms “first”, “second”, “third”, “fourth” or the like can be used in the present disclosure to describe various structures, but these structures are not limited by the terms. The terms are only used to distinguish a first structure from another structure.

Finally, it is to be noted that the foregoing embodiments are only used for describing the technical solutions of the present disclosure, rather than limiting the present disclosure. Although the present disclosure has been described in detail by the foregoing embodiments, a person of ordinary skill in the art should understood that modifications can still be made to the technical solutions recorded in the foregoing embodiments or equipment replacements can be made to some or all of the technical features, and these modifications or replacements do not make the essence of the corresponding technical solutions depart from the scope of the technical solutions in the embodiments of the present disclosure.

### INDUSTRIAL APPLICABILITY

The present disclosure provides a method for controlling the surface glossiness of a metal workpiece and a method for preparing a metal film. The surface glossiness of the metal workpiece in the reaction chamber is improved by using the method for controlling the surface glossiness of a metal workpiece. According to the theory of heat radiation and heat reflection, when there is a metal workpiece with a high glossiness in the reaction chamber, the surface temperature and heat uniformity of the metal film can be improved, so that the resistivity of the metal film is reduced and the thickness uniformity of the metal film is improved. Meanwhile, by using the control method according to the present disclosure, it is convenient and fast to treat the metal workpiece at a high success rate, the service life of the metal workpiece can be prolonged, and the production cost can be reduced.

1. A method for controlling the surface glossiness of a metal workpiece, comprising:
providing a metal workpiece;
detecting the surface glossiness of the metal workpiece to obtain a first detection value;
when the first detection value is less than or equal to a first threshold, treating the metal workpiece by a first treatment process so that the surface glossiness of the metal workpiece is not less than a second threshold;
when the first detection value is greater than the first threshold but less than the second threshold, treating the metal workpiece by a second treatment process so that the surface glossiness of the metal workpiece is not less than the second threshold; and
when the first detection value is greater than or equal to the second threshold, not treating the metal workpiece so that the surface glossiness of the metal workpiece is not less than the second threshold.

2. The control method according to claim 1, wherein the detecting the surface glossiness of the metal workpiece to obtain a first detection value comprises:
detecting glossiness of a plurality of surface regions of the metal workpiece to obtain a plurality of glossiness detection values, obtaining an average glossiness detection value according to the plurality of glossiness detection values, and using the average glossiness detection value as a first detection value.

3. The control method according to claim 1, wherein the detecting the surface glossiness of the metal workpiece to obtain a first detection value comprises:
detecting glossiness of a plurality of surface regions of the metal workpiece to obtain a plurality of glossiness detection values, comparing the plurality of glossiness detection values to obtain the smallest glossiness detection value, and using the smallest glossiness detection value as a first detection value.

4. The control method according to claim 1, wherein the treating the metal workpiece by a first treatment process comprises:
treating the metal workpiece in a first acid solution for 15 to 25 min, taking the metal workpiece out and treating the metal workpiece in a first alkali solution for 20 to 40 min, and taking the metal workpiece out and treating the metal workpiece in a second acid solution for 5 to 15 s;
detecting surface glossiness of the treated metal workpiece to obtain a second detection value; and
if the second detection value is less than the second threshold, treating the treated metal workpiece in the second acid solution for 5 to 15 s, detecting surface glossiness of the metal workpiece newly treated, and replacing previous second detection value with the surface glossiness value newly obtained as the second detection value until the second detection value is not less than the second threshold.

5. The control method according to claim 4, wherein the first acid solution is one or more of hydrochloric acid, nitric acid and acetic acid; the first alkali solution is sodium hydroxide solution; and, the second acid solution is one or more of hydrochloric acid, nitric acid and acetic acid.

6. The control method according to claim 1, wherein the treating the metal workpiece by a second treatment process comprises:
treating the metal workpiece in a second alkali solution for 40 to 60 min, taking the metal workpiece out and treating the metal workpiece in a third acid solution for 5 to 15 s;
detecting surface glossiness of the treated metal workpiece to obtain a third detection value; and
if the third detection value is less than the second threshold, treating the treated metal workpiece in the third acid solution for 5 to 15 s, detecting the surface glossiness of the metal workpiece newly treated, and replacing previous third detection value with the surface glossiness value newly obtained as the third detection value until the third detection value is not less than the second threshold.

7. The control method according to claim 6, wherein the second alkali solution is sodium carbonate solution, and the third acid solution is one or more of hydrochloric acid, nitric acid and acetic acid.

8. The control method according to claim 1, wherein the first threshold is 0 to 200 GU, the second threshold is 150 to 500 GU, and the first threshold is less than the second threshold.

9. The control method according to claim 1, after the surface glossiness of the metal workpiece is not less than the second threshold, the control method further comprising: detecting glossiness of different surface regions of the metal workpiece to obtain a plurality of fourth detection values, a difference between any two fourth detection values being less than 20 GU.

10. A metal workpiece, which is formed with a method for controlling a surface glossiness of a metal workpiece, the method comprising:
providing a metal workpiece;
detecting the surface glossiness of the metal workpiece to obtain a first detection value;
when the first detection value is less than or equal to a first threshold, treating the metal workpiece by a first treatment process such that the surface glossiness of the metal workpiece is not less than a second threshold;
when the first detection value is greater than the first threshold but less than the second threshold, treating the metal workpiece by a second treatment process such that the surface glossiness of the metal workpiece is not less than the second threshold; and
when the first detection value is greater than or equal to the second threshold, not treating the metal workpiece, such that the surface glossiness of the metal workpiece is not less than a second threshold.

11. The metal workpiece according to claim 10, wherein the second threshold is 150 to 500 GU.

12. The metal workpiece according to claim 10, wherein, in the metal workpiece, a difference in glossiness between any two surface regions is less than 20 GU.

13. A method for preparing a metal film using a metal workpiece, a surface glossiness of the metal workpiece being not less than a second threshold, the method comprising:
determining a preset temperature according to a process for preparing a metal film;
selecting a metal workpiece with a certain surface glossiness according to the preset temperature;
mounting the metal workpiece in a reaction chamber; and
in the reaction chamber, finely adjusting a temperature in the reaction chamber according to the surface glossiness of the metal workpiece, and forming a metal film by a film deposition method.

14. The preparation method according to claim 13, wherein the selecting a metal workpiece with a certain surface glossiness according to the preset temperature comprises:
selecting a metal workpiece with a surface glossiness of 150 to 500 GU when the preset temperature is 450° C. to 550° C.

15. The preparation method according to claim 13, wherein the selecting a metal workpiece with a certain surface glossiness according to the preset temperature comprises:
selecting a metal workpiece with a surface glossiness of 240 to 500 GU when the preset temperature is 450° C. to 500° C.

16. The preparation method according to claim 13, wherein the selecting a metal workpiece with a certain surface glossiness according to the preset temperature comprises:
selecting a metal workpiece with a surface glossiness of 150 to 300 GU when the preset temperature is 500° C. to 550° C.

17. The preparation method according to claim 13, wherein the method for preparing a metal film comprises:
obtaining glossiness-resistivity curves at a plurality of set temperatures, each of the set temperatures corresponding to one glossiness-resistivity curve;
determining the preset temperature according to the process for preparing a metal film, so as to determine the glossiness-resistivity curve;
using a resistivity of the metal film to be formed as a preset resistivity, and finding, from the determined glossiness-resistivity curve, the glossiness corresponding to the preset resistivity so as to determine the metal workpiece to be used;
mounting the metal workpiece in the reaction chamber; and
in the reaction chamber, finely adjusting the temperature in the reaction chamber according to the surface glossiness of the metal workpiece, and forming the metal film by the film deposition method.

18. The preparation method according to claim 17, wherein the obtaining glossiness-resistivity curves comprises:
in a reaction chamber, setting a temperature in the reaction chamber as the set temperature, and forming metal films with different resistivity by mounting metal workpieces with different surface glossiness, to obtain linear curves of glossiness and resistivity, one glossiness corresponding to one resistivity.

19. The preparation method according to claim 13, wherein a resistivity of the metal film is 2000 to 2500 μΩ·cm.
